(19) United States
(12) Patent Application Publication
(10) Pub. No.: US 2025/0306075 A1
(43) Pub. Date: Oct. 2, 2025

(54) MONITOR FOR AVIONICS CAN BUS SOLUTIONS

(71) Applicant: Rockwell Collins, Inc., Cedar Rapids, IA (US)

(72) Inventors: Eric N. Anderson, Marion, IA (US); Matthew P. Corbett, Mount Vernon, IA (US)

(21) Appl. No.: 18/617,108

(22) Filed: Mar. 26, 2024

(51) Int. Cl. G01R 29/033; G01R 29/027; H04L 1/20

(52) U.S. Cl. CPC G01R 29/033; G01R 29/0276; H04L 1/205

(57) ABSTRACT

A monitor for a node of a time division multiple access (TDMA) data bus comprises a logic device configured to calculate a metric of bandwidth use of the TDMA data bus based on monitored signals transmitted by the node, compare of the metric of bandwidth calculated with an expected metric of bandwidth use for the node, determine that a babbling node failure has occurred in response to the metric of bandwidth calculated exceeding the expected metric of bandwidth use for the node, and issue a control signal to reset the node in response to a detected babbling node failure being determined.

### FIELD OF THE INVENTION

The present disclosure is directed generally to a time division multiple access (TDMA) data bus and, more particularly, to blocking babbling node failure from disrupting data transmission on the TDMA data bus.

### BACKGROUND

TDMA data buses, including controller area network (CAN)-based field buses, allow multiple devices to communicate over a shared medium. Multiple devices or nodes are connected to a common bus to communicate with each other. The CAN protocol allows the nodes to transmit and receive data in an orchestrated fashion to avoid transmission of data resulting in bus collisions. CAN-based field buses are generally attractive as next generation field bus solutions for aviation. The bus arbitration mechanisms used by commercial off the shelf CAN controllers are very effective but do not provide a sufficiently independent protection method to prevent a failed node from transmitting excessively, thereby reducing or eliminating bus access by other nodes.

### SUMMARY

In one aspect, a monitor for a node of a time division multiple access (TDMA) data bus comprises a logic device configured to calculate a metric of bandwidth use of the TDMA data bus based on monitored signals transmitted by the node, compare of the metric of bandwidth calculated with an expected metric of bandwidth use for the node, determine that a babbling node failure has occurred in response to the metric of bandwidth calculated exceeding the expected metric of bandwidth use for the node, and issue a control signal to reset the node in response to a detected babbling node failure being determined.

In another aspect, a multi-drop, multi-master CAN bus comprising a plurality of nodes and a plurality of monitors, each monitor of the plurality of monitors comprising a receiver and a logic device. The receiver is configured to receive data signals transmitted by a single node of the plurality of nodes to the CAN bus. The logic device is configured to calculate a metric of bandwidth use of the CAN data bus based on monitored signals transmitted by the node to the monitor, compare of the metric of bandwidth calculated with an expected metric of bandwidth use for the node, determine that a babbling node failure has occurred in response to the metric of bandwidth calculated exceeding the expected metric of bandwidth use for the node, and issue a control signal to reset the node in response to a detected babbling node failure being determined.

In yet another aspect, a method of preventing a babbling node failure of a single node from disrupting a time division multiple access (TDMA) data bus comprising a plurality of nodes is disclosed. The method includes calculating a metric of bandwidth use of the TDMA data bus based on monitored signals transmitted by the node to the monitor, comparing of the metric of bandwidth use calculated with an expected metric of bandwidth use for the node, determining that a babbling node failure has occurred in response to the metric of bandwidth calculated exceeding the expected metric of bandwidth use for the node, and issuing a control signal to reset the node in response to a detected babbling node failure being determined.

The present summary is provided only by way of example, and not limitation. Other aspects of the present disclosure will be appreciated in view of the entirety of the present disclosure, including the entire text, claims and accompanying figures.

### BRIEF DESCRIPTION OF THE DRAWINGS

FIG. 1 is a block diagram of a TDMA data bus with independent monitors for each of a plurality of nodes.

FIGS. 2A-2C are illustrative examples of schemes for data transmission assessment.

FIG. 3 is a block diagram of a node on the TDMA data bus and monitor according to one embodiment of the present disclosure.

FIG. 4 is a block diagram of a node on the TDMA data bus and monitor according to another embodiment of the present disclosure.

FIG. 5 is a block diagram of a node on the TDMA data bus and a monitor according to yet another embodiment of the present disclosure.

FIG. 6 is a block diagram of a device with integrated monitor logic.

FIG. 7 is a block diagram of a device having an independent IP block for making CAN transmit signal data available to a separate monitor.

FIG. 8 is a flow chart of a method for monitoring a node on the TDMA data bus and responding to a detected babbling node failure.

While the above-identified figures set forth embodiments of the present invention, other embodiments are also contemplated, as noted in the discussion. In all cases, this disclosure presents the invention by way of representation and not limitation. It should be understood that numerous other modifications and embodiments can be devised by those skilled in the art, which fall within the scope and spirit of the principles of the invention. The figures may not be drawn to scale, and applications and embodiments of the present invention may include features, steps and/or components not specifically shown in the drawings.

### DETAILED DESCRIPTION

The present disclosure is directed to a monitor and means for monitoring a node on a TDMA data bus, such as, but not limited to, a CAN-based field bus for aviation applications. The monitor or means for monitoring is configured to command a reset of a node on the TDMA data bus or disconnect the node from the TDMA data bus when an excessive level of transmissions from the node on the TDMA data bus (also known as a “babbling node” failure) is detected. A babbling node failure can occur when a data bus node transmits continuously or more frequently than authorized, transmits larger messages than authorized, and/or transmits out of sequence (e.g., erroneously transmits high-priority messages or transmits high priority messages at erroneous times) causing a disruption in communication of properly operating nodes on the TDMA data bus. The excessive level of transmissions can be uniquely defined and/or tailorable to the monitored data bus node. As used herein, “babbling node failure” refers to a user-defined unauthorized data transmission as described further herein. The monitor and means for monitoring are configured to be communicatively coupled to a single node in a TDMA data bus such that only data transmissions by the single node are received and assessed. Each node in a TDMA data bus can be independently monitored by a separate monitor or means for monitoring as described further herein. The disclosed TDMA data bus solutions provide a low-cost approach to ensuring that devices with TDMA interfaces can meet expected aviation safety requirements including integrity and no single fault expectations.

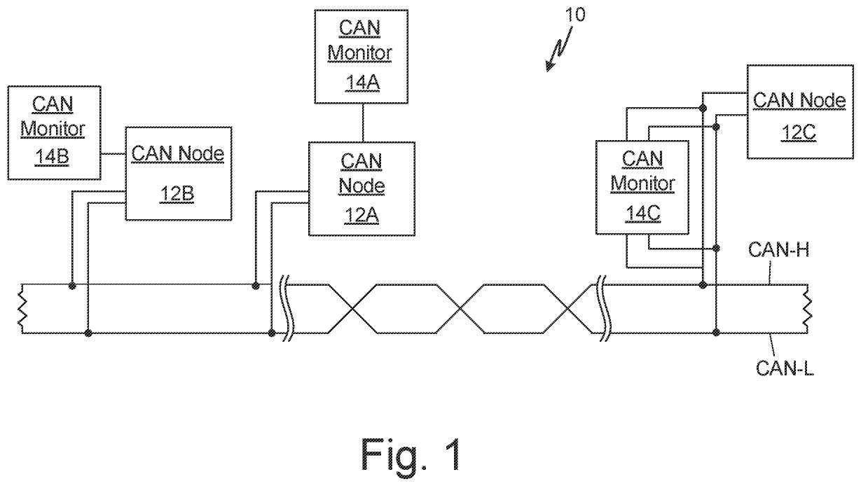

FIG. 1 is a simplified block diagram of a monitored TDMA data bus according to multiple embodiments of the present disclosure. The TDMA data bus can be, but is not limited to, a CAN bus, designed to meet avionics safety requirements. It will be understood by one of ordinary skill in the art that the monitors and various embodiments disclosed herein for monitoring nodes of a CAN bus can be used or adapted for use with other TDMA data bus applications.

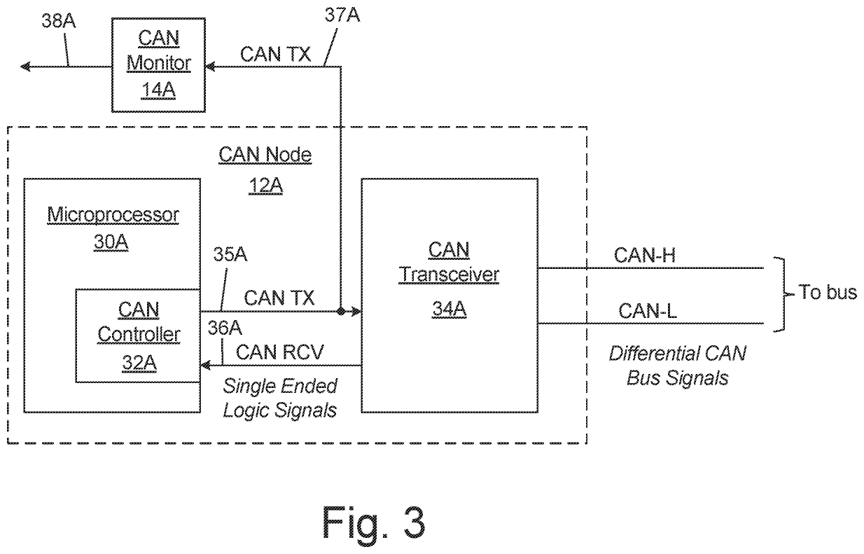

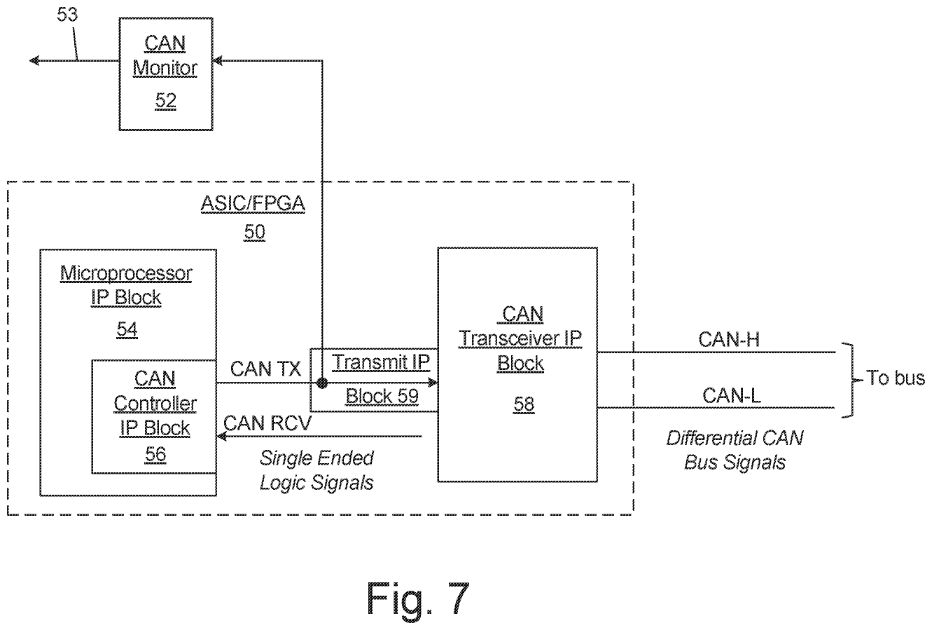

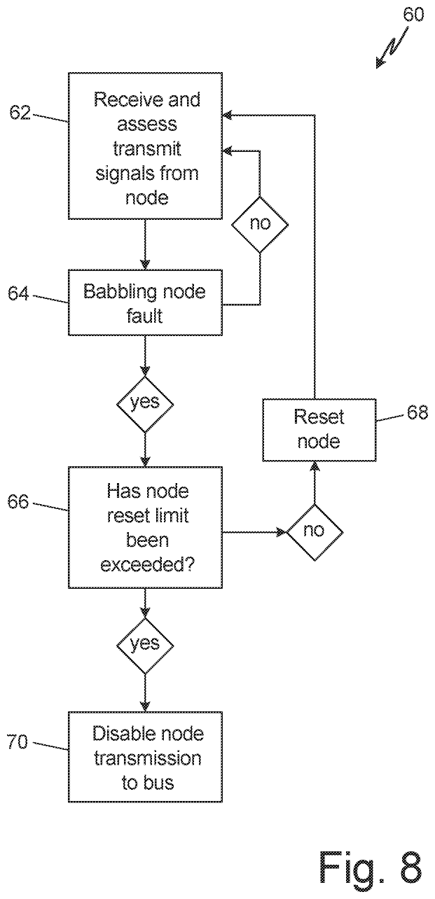

FIG. 1 shows CAN bus 10, nodes 12A-12C, monitors 14A-14C, and CAN-H and CAN-L wires. CAN bus 10, absent monitors 14A-14C, is a multi-drop, multi-master communication protocol, as known in the art, configured to allow a plurality of nodes (e.g., nodes 12A-12C) to communicate over a shared physical communication bus (CAN bus 10). Each transmitting node 12A-12C monitors CAN bus 10 while transmitting data. A process of arbitration determines which node transmits data at any time to avoid collision (i.e., when two or more nodes transmit data at the same time) and delays. Data is transmitted over a pair of twisted wires, CAN-H and CAN-L. Monitors 14A-14C are communicatively coupled to nodes 12A-12C, respectively, and are configured to detect babbling node failures and reset and disconnect respective nodes 12A-12C to stop and/or prevent babbling node failures from disrupting communication of properly operating nodes 12A-12C on CAN bus 10. FIG. 1 is a simplified block diagram illustrating three monitor-node coupling configurations, which are described and illustrated in further detail in FIGS. 3-5. CAN bus 10 can include any single monitor-node coupling configuration illustrated in FIGS. 1 and 3-5 or discussed further herein (i.e., configurations shown in FIGS. 7 and 8) or any combination of monitor-node coupling configurations disclosed herein. The inclusion of multiple monitor-node coupling configurations in a single CAN bus is for illustrative purposes only and is not intended to be limiting.

Nodes 12A-12C are connected to CAN bus 10 and configured to transmit data to CAN bus 10 and receive data transmissions from CAN bus 10. Nodes 12A-12C can be any type of device, as known in the art, including but not limited to, sensors, actuators, computers, etc. Each node 12A-12C includes a microprocessor, controller, and transceiver. Each node 12A-12C has a defined or authorized transmitting profile, which can include periodic data transmissions (e.g., data transmitted at regular intervals), aperiodic data transmissions (e.g., blocks of data transmitted in response to an event), and a combination thereof.

Each monitor 14A-14C is communicatively coupled to a single node 12A-12C and is configured to monitor data transmission of the single node 12A-12C. Each monitor 14A-14C includes a receiver configured to receive a logic level data transmission signal from the node and a logic device to assess the data transmissions and detect babbling node failures of the respective node 12A-12C. The logic device can be a programmable logic device, such as a field programmable gate logic (FPGA) device or a fixed logic or application specific integrated circuit (ASIC). Monitors 14A-14C can operate independent of each other and of nodes 12A-12C to which they are not communicatively coupled. Monitors 14A-14C can be configured to detect a babbling node failure of the respective node 12A-12C and command a reset of the respective node 12A-12C when a babbling node failure is detected and/or disable data transmission from the respective node 12A-12C by disconnecting the respective node 12A-12C from CAN bus 10 or otherwise inhibiting transmission thereby.

As described further herein, monitors 14A-14C can be configured to issue a reset to their respective nodes 12A-12C each time a babbling node failure is detected and including when a reset fails to return the node 12A-12C to a normal operating state. If multiple resets fail to return the node 12A-12C to proper operation, the monitor 14A-14C can disable network transmissions by disconnecting the node 12A-12C from CAN bus 10 or holding a card or line replaceable unit (LRU) of the node 12A-12C in a down or reset state. Disconnection can include, for example, physically disconnecting the malfunctioning node 12A-12C from CAN bus 10 (e.g., interrupting a connection between node 12A-12C and CAN bus 10) or removing power to node 12A-12C (e.g., disconnecting node 12A-12C from a power source or turning node 12A-12C off). The malfunctioning node 12A-12C can be disabled for the duration of operation of CAN bus 10 (e.g., duration of a flight) or indefinitely, until the malfunctioning node 12A-12C can be repaired or replaced.

An expected consumption of bus bandwidth over time for a node 12A-12C on CAN bus 10 can be defined in the logic device of the respective monitor 14A-14C to enable the monitor 14A-14C to detect a babbling node failure. Such consumption of bus bandwidth can include, for example, a percentage of bus bandwidth used for data transmission, a data transmission rate, a data transmission profile, and/or other measures of data transmission for a node 12A-12C. A data transmission rate can include, for example, a transmission rate for periodic data (i.e., having predefined frequency of data transmission and data transmission duration). A data transmission profile can include a predefined periodic data transmission rate and/or one or more authorized aperiodic data transmissions (e.g., blocks of data transmitted in response to an event). Aperiodic data can have a predefined data transmission duration, schedule, and/or message size. A data transmission profile can additionally include predefined time intervals between aperiodic data transmissions and/or between aperiodic and periodic data transmissions. Priority of all periodic and aperiodic data transmissions can also be defined for the node being monitored.

Each monitor 14A-14C can assess the percentage of bus bandwidth used over a defined time interval, data transmission rate, data transmission profile, and/or other measure of data transmission of the respective node 12A-12C and can issue a reset command to the respective node 12A-12C when the respective node 12A-12C transmits data outside of (i.e., more than) the defined data transmission metric, indicating a babbling node failure. The defined data transmission metric can be tailorable for each node 12A-12C, either in discrete steps (e.g., 1%, 5%, 10%, 20%, etc. of bus bandwidth in a defined time period) or as a loadable transmission profile, accounting for periodic data and aperiodic data transmissions. A loadable transmission profile can set the limits for data transmission. For example, a loadable transmission profile may define, for a period of time, a mix of periodic data transmission signals, none of which will take more than a defined duration and will be spaced by intervals of defined duration, and, additionally, aperiodic data transmission signals, none of which exceed a defined duration. If either the periodic data transmission duration limit or aperiodic data transmission duration limit is exceeded, the monitor 14A-14C can issue a reset command to the respective node 12A-12C. In another embodiment, the loadable transmission profile may define a bandwidth consumption limit (e.g., percent of a time window) for combined periodic and aperiodic data transmission and the monitor 14A-14C can be configured to issue a reset to a respective node 12A-12C if the data transmitted by the node 12A-12C exceed the defined bandwidth consumption limit. Various monitoring schemes can be used to assess data transmissions of nodes 12A-12C as described in further detail below.

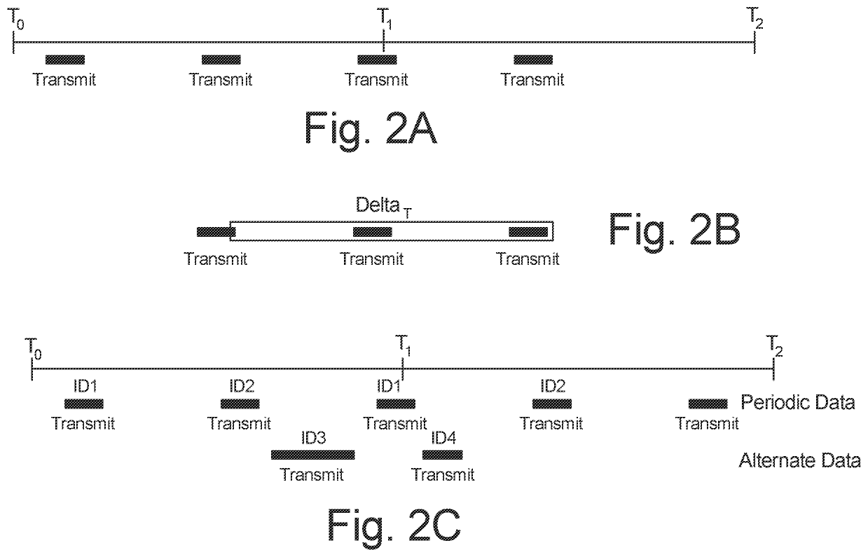

Monitors 14A-14C can continuously assess consumption of bus bandwidth by their respective nodes 12A-12C. FIGS. 2A-2C are non-exhaustive illustrative examples of schemes for data transmission assessment by monitors 14A-14C. FIGS. 2A and 2B illustrate simple percentage of bus bandwidth consumption monitoring schemes. As shown in FIG. 2A, data transmission can be divided into fixed time intervals (T₀ to T₁ and T₁ to T₂). The monitor 14A-14C can be configured to detect a babbling node failure by assessing discrete time interval totals or averages of data transmission from the node 12A-12C to CAN bus 10. As illustrated in FIG. 2A, a node transmission profile may include periodic data transmission in which each data transmission has a fixed duration and is transmitted with a fixed frequency. In the illustrative example, each data transmission consumes 10% of the defined time interval and up to three data signals are transmitted in each time interval, meaning the total bus bandwidth consumption of the node for the defined time interval is equal to or less than 30%. FIG. 2B illustrates a sliding time window in which a rolling total or rolling average of data transmission from the node 12A-12C to CAN bus 10 can be maintained. In this example, the transmission profile again includes periodic data transmission in which each data transmission has a fixed duration and is transmitted with a fixed frequency. The time window, represented by Delta T, is continuously advancing. As shown in FIG. 2A, the total or average data transmission within any time window can be monitored and determined, and then compared with the expected total or average data transmission. In both examples, shown in FIGS. 2A and 2B, the monitor 14A-14C can simply monitor the total or average bus bandwidth consumption. Any monitored data transmission exceeding the expected total or average bus bandwidth can be identified as a babbling node failure.

FIG. 2C illustrates a more complex transmission profile for a node 12A-12C, which includes both periodic data transmission (ID1 and ID2) and aperiodic data transmission (ID3 and ID4). Each data transmission has an associated CAN frame ID and transmission characteristic (e.g., data transmission frequency, duration or message size, and priority). Each periodic data transmission ID1 and ID2 has a fixed duration and is transmitted with a known frequency (e.g., approximately three or less data transmissions in each time window T₀-T₂). Each aperiodic data transmission ID3 and ID4 can have a defined message size or duration and priority. In some transmission profiles, the data transmissions of ID3 and ID4 may include more data and thus require a larger time window (e.g., T₀ to T₂) for transmission. In such scenario, the total or average percentage of bus bandwidth consumption may be monitored, combining the periodic and aperiodic data. Alternatively, in more complex scenarios, the explicit transmission profile can be defined including using message information, such as a CAN frame identified (ID1, ID2, ID3, ID4) to determine if each data transmission is an expected output of the node 12A-12C, if the size of each transmission is within the specification for the particular node 12A-12C, and/or if the rate of each data transmission is within the specification for that specific output. In this scenario, any data transmissions by a node 12A, 12B or 12C that are not defined in the corresponding transmission profile could be considered a babbling node failure and the monitor 14A-14C could command a reset of the node 12A-12C.

Each monitor 14A-14C can be configured to receive tailorable inputs to assess the unique data transmission profile of the node 12A-12C to which the monitor 14A-14C is communicatively coupled. In one embodiment, tailorable inputs can be provided via pin programming logic. For example, pin programming logic can be fully defined in monitors 14A-14C. A user can determine which pins to ground or open to define a transmission metric limit tailored to the defined transmission characteristics or transmission profile of the node 12A-12C. In other embodiments, monitors 14A-14C can be configured to receive a transmission profile from an integrated or external memory. Monitors 14A-14C can include programmable logic devices to assess data transmissions of nodes 12A-12C. Algorithms tailored to the data transmission profile of each node 12A-12C can be developed to assess and detect babbling node failures of the node 12A-12C. Importantly, each monitor 14A-14C is configured to assess the unique data transmission characteristics of the node 12A-12C to which the monitor 14A-14C is communicatively coupled.

FIG. 3 is a block diagram of a single node on the TDMA data bus and monitor communicatively coupled to the node according to one embodiment of the present disclosure. FIG. 3 shows CAN bus 10, node 12A, monitor 14A, CAN-H and CAN-L wires, microprocessor 30A, CAN controller 32A, CAN transceiver 34A, monitor output 38A, transmitting data CAN TX conductor 35A, receiving data CAN RCV conductor 36A, transmitting signals CAN TX, and receiving signals CAN RCV. Node 12A is connected to CAN bus 10. Node 12A is configured to receive data transmissions from CAN bus 10 and transmit data to CAN bus 10 via CAN transceiver 34A. Data transmitted and received over transmitting data CAN TX conductor 35A and receiving data CAN RCV conductor 36A, respectively, are single ended logic signals. Differential CAN bus signals (e.g., a sequence of binary logic levels, which can be called dominant and recessive states) are transmitted via CAN-H and CAN-L wires. Monitor 14A is configured to receive transmitting signals (via CAN TX conductor 35A) from node 12A, assess the received transmitting signals, and issue commands via monitor output 38A to reset and/or disable node 12A.

Monitor 14A can be an independent device (e.g., processor, ASIC, FPGA, etc.) separate from node 12A but communicatively coupled to node 12A. Monitor 14A can be communicatively coupled to node 12A via direct connection (via line 37A) to transmit conductor CAN TX between CAN controller 32A and CAN transceiver 34A. Monitor 14A can be uniquely configured to monitor and assess data transmission from node 12A via transmit signals transmitted via the CAN TX conductor 35A as described above. If monitor 14A detects a babbling node failure of node 12A, monitor 14A can issue a reset command via monitor output 38A to reset node 12A. For example, output 38A can include a reset conductor that conductively couples to a reset input port of CAN node 12A. When monitor 14A determines that node 12A has become a babbling node, monitor 14A can assert a reset signal upon the reset conductor, thereby causing node 12A to reset. Output 38A can include other conductors, which can be used to communicate operational status of node 12A to other components or other systems, for example. Monitor 14A can continue to assess data transmission from node 12A following reset to determine if the reset has returned node 12A to normal operation. If the reset fails to return node 12A to normal operation, monitor 14A can issue additional reset commands and/or can issue a command to disconnect node 12A from CAN bus 10 or disable further data transmissions to CAN bus 10, as previously described.

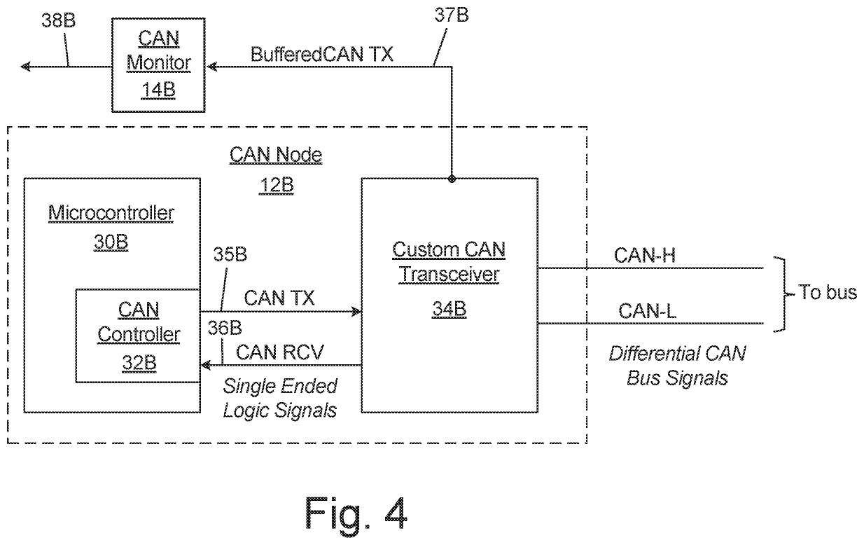

FIG. 4 is a block diagram of a node on the TDMA data bus and monitor communicatively coupled to the node according to another embodiment of the present disclosure. FIG. 4 shows CAN bus 10, node 12B, monitor 14B, CAN-H and CAN-L wires, microprocessor 30B, CAN controller 32B, CAN transceiver 34B, monitor output 38B, transmitting data CAN TX conductor 35B, receiving data CAN RCV conductor 36B, buffered CAN TX conductor 37B, transmitting signals CAN TX, buffered CAN TX signals, and receiving signals CAN RCV. Node 12B is connected to CAN bus 10. Node 12B is configured to receive data transmissions from CAN bus 10 and transmit data to CAN bus 10 via CAN transceiver 34B, transmitting CAN TX conductor 35B, and receiving CAN RCV conductor 36B, as described with respect to FIG. 3. Monitor 14B is configured to receive transmitting signals (CAN TX) from node 12B, assess the received transmitting signals, and issue commands via monitor output 38B to reset and/or disable node 12B.

Monitor 14B can be an independent device (e.g., processor, ASIC, FPGA, etc.) separate from node 12B but communicatively coupled to node 12B. In some embodiments, it may not be possible to access the independent transmit CAN TX conductor 35B, as provided in the coupling configuration of FIG. 3. In this scenario, monitor 14B may be communicatively coupled to node 12B via direct connection to an output of CAN transceiver 34B. CAN transceiver 34B can be a custom CAN bus transceiver device configured to make the logic level transmit signal buffered CAN TX passively available to monitor 14B. As discussed above, monitor 14B can be uniquely configured to monitor and assess data transmission from node 12B via the buffered CAN TX conductor 37B. If monitor 14B detects a babbling node failure of node 12B, monitor 14B can issue a reset command via monitor output 38B to reset node 12B, as previously described. Monitor 14B can continue to assess data transmission from node 12B via CAN transceiver 34B following reset to determine if the reset has returned node 12B to normal operation. If the reset fails to return node 12B to normal operation, monitor 14B can issue additional reset commands and/or can issue a command to disconnect node 12B from CAN bus 10 or disable further data transmissions to CAN bus 10, as previously described.

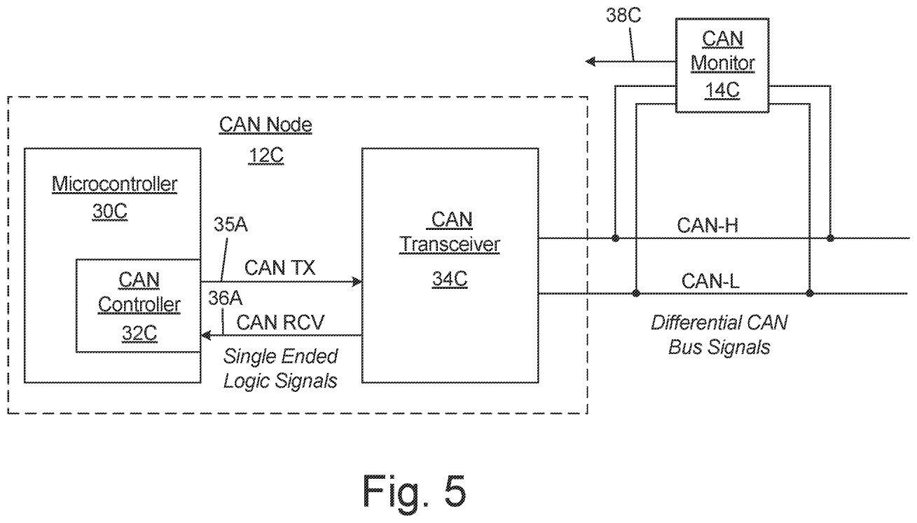

FIG. 5 is a block diagram of a node on the TDMA data bus, and a monitor communicatively coupled to the node according to yet another embodiment of the present disclosure. FIG. 5 shows CAN bus 10, node 12C, monitor 14C, CAN-H and CAN-L wires, microprocessor 30C, CAN controller 32C, CAN transceiver 34C, monitor output 38C, transmitting data CAN TX conductor 35C, receiving data CAN RCV conductor 36C, transmitting signals CAN TX, and receiving signals CAN RCV. Node 12C is connected to CAN bus 10. Node 12C is configured to receive data transmissions (receiving signals CAN RCV) from CAN bus 10 and transmit data (CAN TX) to CAN bus 10 via CAN transceiver 34C. Monitor 14C is configured to receive differential CAN bus signals via CAN-H and CAN-L wires from CAN bus 10 and issue commands via monitor output 38C to reset and/or disable node 12C.

Monitor 14C can be an independent device (e.g., processor, ASIC, FPGA, etc.) separate from node 12C but communicatively coupled to the differential CAN bus signals (CAN-H and CAN-L). Monitor 14C has multiple wired connections, two on each of the CAN-H and CAN-L wires. Monitor 14C can be connected to CAN bus 10 or to the stub connecting CAN transceiver 34A to CAN bus 10. Connections on each of the CAN-H and CAN-L wires can be sufficiently spaced to identify signal delays. Timers can determine signal propagation direction, and thus if the data signals are being received or transmitted by node 12C. Monitor 14C can function according to the same logic as provided in monitors 14A and 14B, however, may include a higher resolution clock or phase differentiation capability to distinguish outgoing data transmissions from node 12C from ingoing data transmissions to node 12C. If monitor 14C detects a babbling node failure of node 12B, monitor 14B can issue a reset command via monitor output 38C to rest node 12C, as previously described. Monitor 14C can continue to assess data transmission from node 12C via the differential CAN bus signals following reset to determine if the reset has returned node 12C to normal operation. If the reset fails to return node 12C to normal operation, monitor 14C can issue additional reset commands and/or can issue a command to disconnect node 12C or to disable further data transmissions to CAN bus 10, as previously discussed.

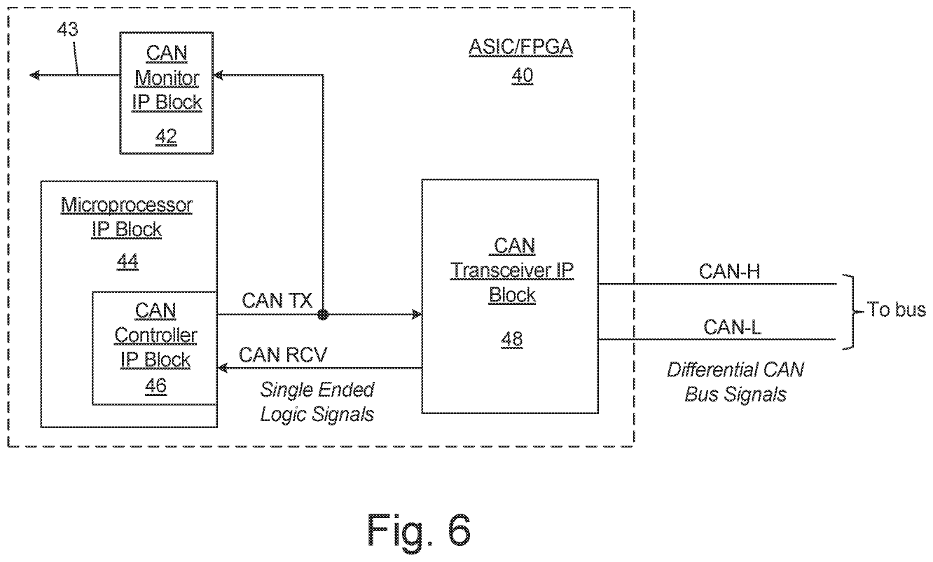

FIG. 6 is a block diagram of a device with integrated monitor logic. FIG. 6 shows CAN bus 10, CAN-H and CAN-L wires, device 40, CAN monitor intellectual property (IP) block 42, output 43, microprocessor IP block 44, CAN controller IP block 46, CAN transceiver IP block 48, transmitting signals CAN TX, and receiving signals CAN RCV. Device 40 is an ASIC or FGPA. In some embodiments, an independent CAN monitor IP block can be provided for an integrated monitor when using commercial or previously defined IP blocks in the development of a custom device (ASIC or FPGA). As used herein, IP blocks are logic units that are the intellectual property of a party. Monitor IP block 42 is the functional set of logic defining a measure of excessive and/or unauthorized transmission indicative of a babbling node failure and rules to issue a command to reset the node or disable data transmission from the node via output 43. Monitor IP block 42 can be the same functional set of logic described above and provided in the independent monitor devices 14A-14C of FIGS. 3-5. In contrast to the embodiments shown in FIGS. 3-5, monitor IP block 42 can be inserted into a custom ASIC or FGPA device 40 with microprocessor IP block 44, CAN controller IP block 46, and CAN transceiver IP block 48.

FIG. 7 is a block diagram of a device having an independent IP block for making CAN transmit signal data available to a separate monitor. FIG. 7 shows CAN bus 10, CAN-H and CAN-L wires, device 50, monitor 52, monitor output 53, microprocessor IP block 54, CAN controller IP block 56, CAN transceiver IP block 58, data transmit IP block 59, transmitting signals CAN TX, and receiving signals CAN RCV. Data transmit IP block 59 can be a custom IP block configured to make CAN TX data available to monitor 52 when using commercial or previously defined IP blocks in the development of a custom ASIC or FPGA device. Data transmit IP block 59 is custom logic to intercept CAN TX data signals between consumer electronics defined logic sets (CAN controller IP block 56 and CAN transceiver IP block 58). Monitor 52 can be an independent device as described in FIGS. 3-5, configured to receive and assess data transmissions from data transmit IP block 52. If monitor 52 detects a babbling node failure of the node, monitor 52 can issue a reset command via monitor output 53 to reset the node, as previously described. Monitor 52 can continue to assess data transmission from data transmit IP block 59 following reset to determine if the reset has returned the node to normal operation and can issue additional reset commands and/or can issue a command to disconnect node or to disable further data transmissions to CAN bus 10, as previously discussed.

The node-monitor configurations disclosed in FIGS. 3-7 are non-exhaustive. Other means for communicatively coupling a monitor device to a node to receive transmission data signals from the node are contemplated. The use of independent monitors or monitor IP blocks for assessing the bandwidth consumption of a single node on a data bus provides a low-cost approach to ensuring that COTS CAN-based interfaces can meet the expected safety requirements for aviation.

FIG. 8 is a flow chart of method 60 for monitoring a node on the TDMA data bus and responding to a detected babbling node failure. In step 62, a monitor receives one or more data transmissions from the node. The monitor can be configured to continuously monitor data transmissions from the node. In step 64, the monitor can determine, via any of the previously described functional logic defined for the node if the data transmissions from the node are indicative of a babbling node failure. As previously discussed, the monitor can assess data transmissions over a defined period of time and determine, for example, if the data transmissions fall within an expected consumption of bus bandwidth over that period of time. For example, as previously described, the monitor can assess the percentage of bus bandwidth used for data transmission, the data transmission rate, the data transmission profile, and/or other measures of data transmission for the node. If the data transmission falls within an expected level, the monitor continues the process of receiving and assessing data transmissions. If at any point, the monitor determines that the level of data transmissions exceeds the expected consumption of bus bandwidth indicating a babbling node failure, the monitor can determine if the babbling node failure immediately follows a node reset in step 66 and, if so, if the number of times the node has been reset exceeds a predefined reset limit. For example, following three unsuccessful resets of the node, the monitor may be configured to disable network data transmissions of the node. If the babbling node failure does not immediately follow a node reset or the maximum number of allowable resets has not been reached, the monitor can issue a command to the node controller to reset (step 68). Following reset, the monitor continues to receive and assess data transmissions from the node. If the monitor determines that the maximum number of unsuccessful resets has been reached following the determination of a babbling node failure, the monitor can issue a command to the node controller to disable data transmission to the data bus (step 70). Disabling data transmission can include, for example, disconnecting the node from the bus or removing power to the node. The node can remain in a disabled state for the duration of operation of the data bus (e.g., duration of a flight) or until the node can be repaired or replaced.

### Discussion of Possible Embodiments

The following are non-exclusive descriptions of possible embodiments of the present invention.

A monitor for a node of a time division multiple access (TDMA) data bus comprises a logic device configured to calculate a metric of bandwidth use of the TDMA data bus based on monitored signals transmitted by the node, compare of the metric of bandwidth calculated with an expected metric of bandwidth use for the node, determine that a babbling node failure has occurred in response to the metric of bandwidth calculated exceeding the expected metric of bandwidth use for the node, and issue a control signal to reset the node in response to a detected babbling node failure being determined.

The monitor of the preceding paragraph can optionally include, additionally and/or alternatively, any one or more of the following features, configurations and/or additional components:

In an embodiment of the monitor of the preceding paragraph, the expected metric of bandwidth use for the node can be a percentage of a bus bandwidth used by the node over a defined time interval.

In an embodiment of the monitor of any of the preceding paragraphs, the expected metric of bandwidth use for the node can be a stored transmission profile comprising a transmission schedule for periodic data and/or aperiodic data.

In an embodiment of the monitor of any of the preceding paragraphs, the metric of bus bandwidth use can be determined by maintaining a rolling total or rolling average of data transmissions from the node to the TDMA bus.

In an embodiment of the monitor of any of the preceding paragraphs, the metric of bus bandwidth use can be determined by assessing a discrete interval total or a discrete interval average of data transmissions from the node to the TDMA data bus.

In an embodiment of the monitor of any of the preceding paragraphs, the metric of bus bandwidth use can be determined by assessing a total or an average of data transmissions according to a transmitted data priority.

In an embodiment of the monitor of any of the preceding paragraphs, the metric of bus bandwidth use can be determined by assessing a total or an average of data transmissions according to a transmitted data type, the transmitted data types including periodic data and aperiodic data.

In an embodiment of the monitor of any of the preceding paragraphs, the programmable logic device can be further configured to issue a control signal to disable the node from transmitting data on the TDMA data bus when the programmable logic device detects a babbling node failure following multiple resets of the node.

In an embodiment of the monitor of any of the preceding paragraphs, disabling the node can include physically disconnecting the node from the TDMA data bus, holding the node in a reset state, or removing power to the node.

In an embodiment of the monitor of any of the preceding paragraphs, the monitor can be integrated into the node.

In an embodiment of the monitor of any of the preceding paragraphs, the monitor can be an independent device communicatively coupled to the node.

In an embodiment of the monitor of any of the preceding paragraphs, the monitor can be communicatively coupled to an output of a transceiver of the node, the output configured to passively transmit a single ended logic signal to the monitor.

In an embodiment of the monitor of any of the preceding paragraphs, the monitor can be communicatively coupled to a transmit line of a controller of the node, the transmit line can be configured to transmit a single ended logic signal to each of the monitor and a transceiver of the node.

In an embodiment of the monitor of any of the preceding paragraphs, the monitor can be connected to differential data signals of the TDMA bus.

In an embodiment of the monitor of any of the preceding paragraphs, the monitor can be communicatively coupled to an intellectual property block configured to make data transmission signals of the node available to the monitor.

In an embodiment of the monitor of any of the preceding paragraphs, the monitor can be communicatively separated from other nodes of TDMA data bus.

A multi-drop, multi-master CAN bus comprising a plurality of nodes and a plurality of monitors, each monitor of the plurality of monitors comprising a receiver and a logic device. The receiver is configured to receive data signals transmitted by a single node of the plurality of nodes to the CAN bus. The logic device is configured to calculate a metric of bandwidth use of the CAN data bus based on monitored signals transmitted by the node to the monitor, compare of the metric of bandwidth calculated with an expected metric of bandwidth use for the node, determine that a babbling node failure has occurred in response to the metric of bandwidth calculated exceeding the expected metric of bandwidth use for the node, and issue a control signal to reset the node in response to a detected babbling node failure being determined.

In an embodiment of the CAN bus of the preceding paragraph, the expected metric of bandwidth use for the node can be a stored transmission profile of the node.

A method of preventing a babbling node failure of a single node from disrupting a time division multiple access (TDMA) data bus comprising a plurality of nodes is disclosed. The method includes calculating a metric of bandwidth use of the TDMA data bus based on monitored signals transmitted by the node to the monitor, comparing of the metric of bandwidth use calculated with an expected metric of bandwidth use for the node, determining that a babbling node failure has occurred in response to the metric of bandwidth calculated exceeding the expected metric of bandwidth use for the node, and issuing a control signal to reset the node in response to a detected babbling node failure being determined.

In an embodiment of the method of the preceding paragraph, calculating a metric of bandwidth use can include at least one of calculating a rolling total or rolling average of transmitted data from the single node to the TDMA bus, calculating a discrete interval total or a discrete interval average of transmitted data from the single node to the TDMA data bus, calculating a total or an average of transmitted data according to a transmitted data priority, and calculating a total or an average of transmitted data according to a transmitted data type, the transmitted data types including periodic data and aperiodic data.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A monitor for a node of a time division multiple access (TDMA) data bus, the monitor comprising:
a logic device configured to:
calculate a metric of bandwidth use of the TDMA data bus based on monitored signals transmitted by the node;
compare of the metric of bandwidth calculated with an expected metric of bandwidth use for the node;
determine that a babbling node failure has occurred in response to the metric of bandwidth calculated exceeding the expected metric of bandwidth use for the node; and
issue a control signal to reset the node in response to a detected babbling node failure being determined.

2. The monitor of claim 1, wherein the expected metric of bandwidth use for the node is a percentage of a bus bandwidth used by the node over a defined time interval.

3. The monitor of claim 1, wherein the expected metric of bandwidth use for the node is a stored transmission profile comprising a transmission schedule for periodic data and/or aperiodic data.

4. The monitor of claim 1, wherein the metric of bus bandwidth use is determined by maintaining a rolling total or rolling average of data transmissions from the node to the TDMA bus.

5. The monitor of claim 1, wherein the metric of bus bandwidth use is determined by assessing a discrete interval total or a discrete interval average of data transmissions from the node to the TDMA data bus.

6. The monitor of claim 1, wherein the metric of bus bandwidth use is determined by assessing a total or an average of data transmissions according to a transmitted data priority.

7. The monitor of claim 1, wherein the metric of bus bandwidth use is determined by assessing a total or an average of data transmissions according to a transmitted data type, the transmitted data types including periodic data and aperiodic data.

8. The monitor of claim 1, wherein the programmable logic device is further configured to issue a control signal to disable the node from transmitting data on the TDMA data bus when the programmable logic device detects a babbling node failure following multiple resets of the node.

9. The monitor of claim 8, wherein disabling the node comprises physically disconnecting the node from the TDMA data bus, holding the node in a reset state, or removing power to the node.

10. The monitor of claim 1, wherein the monitor is integrated into the node.

11. The monitor of claim 1 being an independent device communicatively coupled to the node.

12. The monitor of claim 11, wherein the monitor is communicatively coupled to an output of a transceiver of the node, the output configured to passively transmit a single ended logic signal to the monitor.

13. The monitor of claim 11, wherein the monitor is communicatively coupled to a transmit line of a controller of the node, the transmit line configured to transmit a single ended logic signal to each of the monitor and a transceiver of the node.

14. The monitor of claim 11, wherein the monitor is connected to differential data signals of the TDMA bus.

15. The monitor of claim 11, wherein the monitor is communicatively coupled to an intellectual property block configured to make data transmission signals of the node available to the monitor.

16. The monitor of claim 1, wherein the monitor is communicatively separated from other nodes of TDMA data bus.

17. A multi-drop, multi-master CAN bus comprising a plurality of nodes and a plurality of monitors, each monitor of the plurality of monitors comprising:
a receiver configured to receive data signals transmitted by a single node of the plurality of nodes to the CAN bus; and
a logic device configured to:
calculate a metric of bandwidth use of the CAN data bus based on monitored signals transmitted by the node to the monitor;
compare of the metric of bandwidth calculated with an expected metric of bandwidth use for the node;
determine that a babbling node failure has occurred in response to the metric of bandwidth calculated exceeding the expected metric of bandwidth use for the node; and
issue a control signal to reset the node in response to a detected babbling node failure being determined.

18. The CAN bus of claim 17, wherein the expected metric of bandwidth use for the node is a stored transmission profile of the node.

19. A method of preventing a babbling node failure of a single node from disrupting a time division multiple access (TDMA) data bus comprising a plurality of nodes, the method comprising:
calculating a metric of bandwidth use of the TDMA data bus based on monitored signals transmitted by the node to the monitor;
comparing of the metric of bandwidth use calculated with an expected metric of bandwidth use for the node;
determining that a babbling node failure has occurred in response to the metric of bandwidth calculated exceeding the expected metric of bandwidth use for the node; and
issuing a control signal to reset the node in response to a detected babbling node failure being determined.

20. The method of claim 19, wherein calculating a metric of bandwidth use comprises at least one of:
calculating a rolling total or rolling average of transmitted data from the single node to the TDMA bus;
calculating a discrete interval total or a discrete interval average of transmitted data from the single node to the TDMA data bus;
calculating a total or an average of transmitted data according to a transmitted data priority; and
calculating a total or an average of transmitted data according to a transmitted data type, the transmitted data types including periodic data and aperiodic data.
